(19) United States
(12) Patent Application Publication
(10) Pub. No.: US 2008/0099891 A1
(43) Pub. Date: May 1, 2008

(54) Semiconductor device and method of manufacturing the same

(75) Inventors: Yutaka Kato, Osaka (JP); Hiroaki Suzuki, Hyogo (JP); Naoto Ueda, Hyogo (JP); Isamu Aokura, Osaka (JP); Takayuki Yoshida, Shiga (JP); Takuma Motofuji, Osaka (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 11/898,502

(22) Filed: Sep. 12, 2007

(30) Foreign Application Priority Data
Oct. 30, 2006 (JP) 2006-293404
Jun. 4, 2007 (JP) 2007-147572

(51) Int. Cl. H01L 23/495; H01L 21/00

(52) U.S. Cl. 257/666; 257/706; 438/122; 257/E23.031; 257/E23.01

(57) ABSTRACT

A semiconductor device including: a semiconductor element 1, a heat conductor 91 opposed to the main surface of the semiconductor element 1, and a sealing resin 6 for sealing at least a part of the semiconductor element 1 and a part of the heat conductor 91, the heat conductor 91 having a surface partially exposed from the sealing resin 6 to the outside, the surface being opposite to the other surface facing the main surface of the semiconductor element 1, wherein the semiconductor device further includes an opening 11 penetrating in the thickness direction on a part of the surface including an exposed part of the heat conductor 91. Since resin can be injected from the opening 11 facing the main surface of the semiconductor element 1, the quality can be stabilized.

### FIELD OF THE INVENTION

The present invention relates to a semiconductor device suitable for mounting a semiconductor element having a large calorific value, and a method of manufacturing the same.

### BACKGROUND OF THE INVENTION

In recent years, electronic equipment has become more multifunctional and has been reduced in size and thickness and accordingly, semiconductor devices have been also reduced in size and thickness and the number of terminals has been increased. As a kind of semiconductor devices for attaining this object, the following is known in addition to a conventional QFP (Quad Flat Package) having laterally protruding external leads: a so-called BGA (Ball Grid Array) package having no external leads but having solder balls arranged in a matrix form on the underside of a semiconductor device, the solder balls acting as external electrodes for electrical connection, an LGA (Land Grid Array) package having external electrodes arranged in a matrix form, and a QFN (Quad Flat Non-lead) package having external electrodes arranged peripherally on the underside of a semiconductor device.

When semiconductor elements having large calorific values are mounted on semiconductor devices of these resin molding types (BGA, LGA, QFP, QFN and so on), it is necessary to prepare designs in consideration of heat dissipation. Japanese Patent Laid-Open No. 8-139223 discloses a semiconductor device configured as follows:

The conventional semiconductor device disclosed in Japanese Patent Laid-Open No. 8-139223 will now be described with reference to the accompanying drawings.

FIG. 19 is a sectional view showing the conventional semiconductor device. FIG. 20 is a perspective view showing a heat conductor of the semiconductor device shown in FIG. 19.

As shown in FIGS. 19 and 20, a conventional semiconductor device 100 is made up of a substrate 3 made of an insulating resin and having wiring patterns 2 formed on both sides of the substrate 3, the wiring patterns 2 being electrically connected to each other through via holes 7, a semiconductor element 1 mounted on the main surface (hereinafter, will be also referred to as a semiconductor element mounting surface) of the substrate 3 via an adhesive 4, thin metal wires 5 for electrically connecting the semiconductor element 1 and the wiring pattern 2 of the substrate 3, ball electrodes 8 arranged in a matrix form on the opposite side from the semiconductor element mounting surface of the substrate 3 and electrically connected to the wiring pattern 2 of the substrate 3, and a heat conductor 9 covering the semiconductor element mounting surface of the substrate 3 and the semiconductor element 1 and having a top surface partially or entirely exposed from a sealing resin 6 to the outside. The heat conductor 9 may be fixed in contact with the substrate 3 via an adhesive and the like (not shown) or may be just brought into contact with the substrate 3 without being fixed.

The heat conductor 9 is made of a material selected from the group consisting of Cu, a Cu alloy, Al, an Al alloy, and an Fe—Ni alloy which have excellent heat conduction, and the heat conductor 9 has a plurality of openings 10 on an inclined portion near the outer periphery.

In the configuration of the semiconductor device 100, heat generated from the semiconductor element 1 is dissipated through the via holes 7 and the ball electrodes 8 and is also dissipated from the main surface of the semiconductor element 1 (from the top surface in FIG. 19) through the heat conductor 9, so that the semiconductor device 100 achieves high heat dissipation.

Further, the effect of dissipating heat from the main surface of the semiconductor element 1 can be further enhanced by providing, for example, a heatsink and the like (not shown) on the top surface of the exposed part of the heat conductor 9 from the sealing resin 6.

Moreover, the plurality of openings 10 are provided on the inclined portion near the outer periphery of the heat conductor 9, so that resin can be easily injected into a gap between the heat conductor 9 and the semiconductor element 1 during resin molding, thereby improving the injection property of the resin.

The following will describe a method of manufacturing the conventional semiconductor device.

As shown in FIG. 21A, the substrate 3 having the wiring patterns 2 formed on both sides is prepared. After that, as shown in FIG. 21B, the semiconductor element 1 is bonded and fixed on the bonding position of the top surface (the semiconductor element mounting surface) of the substrate 3 via the adhesive 4, so that the semiconductor element 1 is mounted on the substrate 3.

Next, as shown in FIG. 21C, the electrode pads (not shown) of the semiconductor element 1 mounted on the substrate 3 and the wiring pattern 2 provided on the top surface of the substrate 3 are electrically connected to each other via the thin metal wires 5.

After that, as shown in FIG. 21D, the heat conductor 9 is brought into contact with the substrate 3 so as to cover the semiconductor element 1. The contact portion of the heat conductor 9 may be fixed to the substrate 3 via an adhesive (not shown) and the like or may be just brought into contact with the substrate 3 without being fixed. As shown in FIG. 20, the heat conductor 9 is formed by drawing a substantially rectangular plate into a rectangular cylinder at the center of the plate and exposing the top of the rectangular cylinder from the sealing resin (see FIG. 19), so that the plate is molded into a cap covering the overall semiconductor element 1. Further, the openings 10 are provided on the inclined portion near the outer periphery of the heat conductor 9.

Next, as shown in FIG. 21E, the substrate 3 which has the semiconductor element 1 mounted thereon, is electrically connected via the thin metal wires 5, and is contacted to the heat conductor 9 is set on a lower die 21A of a sealing die 21 and is sealed with an upper die 21B of the sealing die 21. In this case, the underside of the upper die 21B of the sealing die 21 and the top surface of the heat conductor 9 are in contact with each other. In this state, the sealing resin 6 is injected in an injection direction 22s from an injection gate 21s provided in the horizontal direction of the upper die 21B of the sealing die 21. As a result, the gap on the top surface of the substrate 3 (above the semiconductor element mounting surface) is covered with the sealing resin 6; meanwhile, the top surface of the heat conductor 9 is exposed from the sealing resin 6 to the outside. Thereafter, the upper die 21B and the lower die 21A of the sealing die 21 are opened after the sealing resin 6 is cured.

Next, as shown in FIG. 21F, the substrate 3 having the top surface sealed with the sealing resin 6 is cut for each semiconductor chip by a rotary blade (not shown), so that the substrate 3 is divided into pieces.

Finally, solder balls are provided to form the ball electrodes 8 on external pad electrodes on the underside of the substrate 3 having been divided into pieces, so that external terminals are configured. Thus the semiconductor device 100 of FIG. 19 can be manufactured.

In the conventional semiconductor device 100, although heat dissipation can be obtained by exposing the top surface of the heat conductor 9 from the sealing resin 6, the thin metal wires 5 are deformed as shown in FIG. 22C. This is because in a resin molding process, resin is injected from the injection gate 21s provided on a side of the semiconductor device (hereinafter, will be referred to as the side gate system).

FIG. 22A is a sectional view showing a state immediately before resin molding is performed by the side gate system. FIG. 22A corresponds to sectional views taken along lines A-A indicated by chain lines in FIGS. 22B and 22C. FIG. 22B is a plan view showing the shapes of the thin metal wires before resin is injected. FIG. 22C is a plan view showing the shapes of the thin metal wires after the resin is injected and showing a flowing pattern of the resin.

As shown in FIG. 22C, the resin is injected from the injection gate 21s in the injection direction 22s so as to ripple with respect to the injection gate 21s. In FIG. 22C, each dotted line indicates a position on which the resin reaches at a certain time.

The amount of deformation of the thin metal wires 5 is proportionate to “the viscosity of the resin”, “the flow rate of the resin”, “the angle of the end of a resin flow with respect to the thin metal wire”, and so on. As shown in FIG. 22B, the thin metal wires 5 are extended in a radial manner from the center of the main surface of the semiconductor element 1. Thus as shown in FIG. 22C, after the completion of the injection of the resin, the thin metal wires 5 near the injection gate or near the opposite side from the injection gate are hardly deformed because an angle is hardly formed with respect to the end of a flow, and the other thin metal wires 5 are deformed according to “the flow rate of the resin”, “the angle of the end of a resin flow with respect to the thin metal wire”, and so on.

Therefore, in resin molding of the conventional side gate system, as the semiconductor device is miniaturized and the number of terminal increases, a spacing between the adjacent thin metal wires 5 decreases in the semiconductor device on which the thin metal wires 5 are extended with a high density. In this case, a short circuit occurs on the thin metal wires 5 due to the deformation of the thin metal wires 5, which becomes a problem.

In order to reduce planar deformation of the thin metal wires 5, as shown in FIG. 23, a method of injecting resin from an injection gate 21t opened on the top surface of a semiconductor device may be adopted (hereinafter, will be referred to as the top gate system).

FIG. 23A is a sectional view showing the top gate system. FIG. 23A corresponds to sectional views taken along lines B-B indicated by chain lines in FIGS. 23B and 23C. FIG. 23B is a plan view showing the shapes of the thin metal wires before resin is injected. FIG. 23C is a plan view showing the shapes of the thin metal wires after resin is injected and showing an injection pattern of the resin.

As shown in FIG. 23C, the resin is injected from the injection gate 21t in an injection direction 22t so as to ripple with respect to the injection gate 21t. In FIG. 23C, each dotted line indicates a position on which the resin reaches at a certain time.

By disposing the injection gate 21t above the center of the semiconductor element 1, all of the thin metal wires 5 radially extended from the center of the semiconductor element 1 hardly form an angle with respect to the end of a flow, so that a semiconductor device of high quality can be manufactured without deforming the thin metal wires 5.

However, in the conventional semiconductor device 100, the heat conductor 9 covers the overall top of the semiconductor element 1 and is exposed from the sealing resin 6 to the outside. Thus it is difficult to dispose a resin injection gate above the semiconductor element 1. For this reason, it is not possible to adopt the top gate system.

Further, although the conventional semiconductor device 100 has the openings 10, the heat conductor 9 covers the overall semiconductor element 1 and thus interferes with the injection of resin during resin molding, so that insufficient filling may occur.

### DISCLOSURE OF THE INVENTION

The present invention is designed in consideration of these points. An object of the present invention is to provide a semiconductor device which can be manufactured with high heat dissipation and stable quality without short-circuiting the thin metal wires of the semiconductor device or causing insufficient filling during a manufacturing process, and a method of manufacturing the same.

In order to attain the object, a semiconductor device of the present invention includes: a semiconductor element, a heat conductor opposed to the main surface of the semiconductor element, and a sealing resin for sealing the semiconductor element and a part of the heat conductor, the heat conductor having a surface partially exposed from the sealing resin to the outside, the surface being opposite to the other surface facing the semiconductor element, wherein the semiconductor device further includes an opening penetrating in the thickness direction on a part of the surface including an exposed part of the heat conductor.

Further, the semiconductor device of the present invention further includes a substrate having a semiconductor element mounting area and a plurality of terminals, wherein the heat conductor is disposed on a semiconductor element mounting surface having the semiconductor element mounting area of the substrate.

Moreover, the semiconductor device of the present invention includes a substrate having a plurality of electrode terminals on one of the surfaces of the substrate, the semiconductor element mounted on the other surface of the substrate, the heat conductor disposed on the other surface of the substrate so as to be opposed to the main surface of the semiconductor element, and the sealing resin for sealing the semiconductor element mounting surface serving as the other surface of the substrate, the semiconductor element, and the heat conductor, the heat conductor having the surface partially exposed from the sealing resin to the outside, the surface being opposite to the other surface facing the main surface of the semiconductor element, wherein the semiconductor device further includes an opening penetrating in the thickness direction on a part of the surface including an exposed part of the heat conductor.

Further, the semiconductor device of the present invention further includes a lead frame having a semiconductor element mounting area and a plurality of terminals including internal and external terminals provided around the semiconductor element mounting area, wherein the heat conductor is disposed on a semiconductor element mounting surface having the semiconductor element mounting area of the lead frame.

Moreover, the semiconductor device of the present invention further includes protrusions protruding to the semiconductor element, the protrusions being disposed on the sides of a part having the opening of the heat conductor.

Furthermore, the protrusions of the heat conductor are integrally formed with the heat conductor.

Additionally, the protrusions of the heat conductor are in contact with the semiconductor element.

Furthermore, the protrusion of the heat conductor includes at least one of a hole and a notch.

The semiconductor device further includes, on a part of the surface having the exposed part of the heat conductor, a recessed portion disposed close to the semiconductor element, the recessed portion partially including an opening.

Furthermore, the recessed portion of the heat conductor is formed into a cone.

The semiconductor device of the present invention further includes a heat conductor having a recessed portion partially formed substantially in parallel with the surface of the semiconductor element.

Furthermore, the recessed portion of the heat conductor is in contact with the semiconductor element.

The semiconductor device of the present invention further includes a step embedded in the sealing resin, the step being disposed on at least one of the outer periphery and the inner periphery of the exposed part of the heat conductor.

Furthermore, the heat conductor has an exposed surface including the step, the exposed surface having an area smaller than that of an unexposed surface being opposite to the exposed surface.

Additionally, the opening of the heat conductor is disposed in the vertical direction relative to the center of the main surface of the semiconductor element.

Furthermore, the heat conductor has protruding supporting portions on the surface opposed to the main surface of the semiconductor element.

Additionally, the heat conductor has supporting portions protruding to the semiconductor element mounting surface of the substrate.

Furthermore, the heat conductor has supporting portions protruding to the semiconductor element mounting surface of the lead frame.

Additionally, the supporting portions of the heat conductor are formed by bending parts of the heat conductor.

Furthermore, the heat conductor has at least three supporting portions.

Additionally, the supporting portions of the heat conductor are in contact with the substrate.

Furthermore, the supporting portions of the heat conductor are in contact with the lead frame.

Additionally, the heat conductor has a part embedded into the sealing resin and the embedded part has a rough surface.

The semiconductor device of the present invention further includes a plurality of thin metal wires for electrically connecting terminals and the semiconductor element.

The semiconductor device of the present invention further includes a plurality of thin metal wires for electrically connecting the substrate and the semiconductor element.

The semiconductor device of the present invention further includes a plurality of thin metal wires for electrically connecting the lead frame and the semiconductor element.

Furthermore, the heat conductor is electrically connected to a ground terminal.

A method of manufacturing a semiconductor device of the present invention includes the steps of: disposing a heat conductor opposed to the main surface of a semiconductor element; and sealing the semiconductor element and a part of the heat conductor with resin, wherein the method further includes the step of forming an opening penetrating in the thickness direction on a part of the heat conductor.

A method of manufacturing a semiconductor device of the present invention includes the steps of: disposing a heat conductor opposed to the main surface of a semiconductor element; and sealing the semiconductor element and a part of the heat conductor with resin, wherein the method further includes the steps of: forming, on a part of the heat conductor, a recessed portion disposed close to the semiconductor element; and forming an opening penetrating in the thickness direction on a part of a portion corresponding to the recessed portion.

The method of manufacturing a semiconductor device of the present invention further includes the step of mounting the semiconductor element on a substrate having a plurality of electrode terminals.

The method of manufacturing a semiconductor device of the present invention further includes the step of mounting the semiconductor element on the semiconductor element mounting area of a lead frame having the semiconductor element mounting area and a plurality of terminals including internal and external terminals integrally provided around the semiconductor element mounting area.

The method of manufacturing a semiconductor device of the present invention further includes the steps of: mounting a sealing die such that a part of a surface of the heat conductor is in contact with the inner wall surface of the sealing die, the surface being opposite to the other surface facing the main surface of the semiconductor element; and performing resin molding by injecting resin into the sealing die, wherein the method further includes the step of forming the opening of the heat conductor such that the opening faces the inner wall surface of the sealing die.

The method of manufacturing a semiconductor device of the present invention includes the steps of: mounting a sealing die such that a part of a surface of the heat conductor is in contact with the inner wall surface of the sealing die, the surface being opposite to the other surface facing the main surface of the semiconductor element; and performing resin molding by injecting resin into the sealing die, wherein the method further includes the step of forming the recessed portion of the heat conductor such that the recessed portion faces the inner wall surface of the sealing die.

A method of manufacturing a semiconductor device of the present invention includes the steps of: mounting a semiconductor element on a substrate, the substrate having a plurality of electrode terminals on one surface and the semiconductor element on the other surface; disposing a heat conductor opposed to the main surface of the semiconductor element; clamping the substrate having the semiconductor element thereon while mounting the substrate in a sealing die, and mounting the sealing die such that a part of a surface of the heat conductor is in contact with the inner wall surface of the sealing die, the surface being opposite to the other surface facing the main surface of the semiconductor element; and injecting resin into the sealing die to seal a semiconductor element mounting surface serving as the other surface of the substrate, the semiconductor element, and the heat conductor with the resin, wherein the method further includes the step of forming an opening penetrating in the thickness direction on a part of a portion of the heat conductor, the portion facing the inner wall surface of the sealing die.

A method of manufacturing a semiconductor device of the present invention includes the steps of: mounting a semiconductor element on a substrate, the substrate having a plurality of electrode terminals on one surface and the semiconductor element on the other surface; disposing a heat conductor opposed to the main surface of the semiconductor element; clamping the substrate having the semiconductor element thereon while mounting the substrate in a sealing die, and mounting the sealing die such that a part of a surface of the heat conductor is in contact with the inner wall surface of the sealing die, the surface being opposite to the other surface facing the main surface of the semiconductor element; and injecting resin into the sealing die to seal a semiconductor element mounting surface serving as the other surface of the substrate, the semiconductor element, and the heat conductor with the resin, wherein the method further includes the steps of: forming a recessed portion on a part of a contact part between the heat conductor and the inner wall surface of the sealing die such that the recessed portion is disposed close to the semiconductor element; and forming an opening penetrating in the thickness direction on a part of a portion corresponding to the recessed portion.

The method of manufacturing a semiconductor device of the present invention further includes the step of performing resin molding by injecting resin from an inlet provided on the opening of the heat conductor.

The method of manufacturing a semiconductor device of the present invention further includes the step of performing resin molding by injecting resin from an inlet having an outside shape smaller than the inner diameter of the opening of the heat conductor.

The method of manufacturing a semiconductor device of the present invention further includes the steps of: mounting a sealing die such that a part of a surface of the heat conductor is in contact with the inner wall surface of the sealing die, the surface being opposite to the other surface facing the main surface of the semiconductor element; and performing resin molding by injecting resin into the sealing die, wherein the method further includes the step of, prior to the step of mounting the substrate in the sealing die, setting a height from a contact surface of the semiconductor element mounting surface of the substrate with the sealing die to the top of the surface opposite to the other surface facing the main surface of the semiconductor element such that the height is larger than the depth of the cavity of the sealing die on the semiconductor element mounting surface.

The method of manufacturing a semiconductor device of the present invention includes the steps of: mounting a sealing die such that a part of a surface of the heat conductor is in contact with the inner wall surface of the sealing die, the surface being opposite to the other surface facing the main surface of the semiconductor element; and performing resin molding by injecting resin into the sealing die, wherein the method further includes the step of, prior to the step of mounting the lead frame in the sealing die, setting a height from a contact surface of the semiconductor element mounting surface of the lead frame with the sealing die to the top of the surface opposite to the other surface facing the main surface of the semiconductor element such that the height is larger than the depth of the cavity of the sealing die on the semiconductor element mounting surface.

The method of manufacturing a semiconductor device of the present invention includes the steps of: mounting a sealing die such that a part of a surface of the heat conductor is in contact with the inner wall surface of the sealing die, the surface being opposite to the other surface facing the main surface of the semiconductor element; and performing resin molding by injecting resin into the sealing die, wherein the method further includes the step of performing resin molding while sucking the exposed surface of the heat conductor to the inner wall surface of the sealing die.

The method of manufacturing a semiconductor device of the present invention includes the steps of: mounting a sealing die such that a part of a surface of the heat conductor is in contact with the inner wall surface of the sealing die, the surface being opposite to the other surface facing the main surface of the semiconductor element; and performing resin molding by injecting resin into the sealing die, wherein the method further includes the step of forming a first protrusion opposed to a step embedded in a sealing resin formed on the inner periphery of the exposed part of the heat conductor, and sealing the step on the inner periphery of the exposed part and the first protrusion with resin while bringing the step and the first protrusion into contact with each other.

The method of manufacturing a semiconductor device of the present invention includes the steps of: mounting a sealing die such that a part of a surface of the heat conductor is in contact with the inner wall surface of the sealing die, the surface being opposite to the other surface facing the main surface of the semiconductor element; and performing resin molding by injecting resin into the sealing die, wherein the method further includes the step of forming a second protrusion opposed to a step embedded in a sealing resin formed on the outer periphery of the exposed part of the heat conductor, and sealing the step on the outer periphery of the exposed part and the second protrusion with resin while bringing the step and the second protrusion into contact with each other.

According to the semiconductor device of the present invention and the method of manufacturing the same, the opening is formed on the heat conductor exposed from the top surface of the sealing resin to the outside in the semiconductor device for mounting a semiconductor element having a large caloric value, so that the resin can be injected from the above. Thus the quality can be stabilized.

According to the present invention, in the semiconductor device having the heat conductor exposed from the sealing resin to the outside, the opening is provided on a part of the exposed part of the heat conductor, enabling resin molding of the top gate system. Thus it is possible to prevent thin metal wires from being short-circuited by the deformation of the thin metal wires.

Further, the supporting portions are provided only on parts of the underside of the heat conductor, improving the flowability of resin. Thus it is possible to prevent failures such as insufficient filling.

### BRIEF DESCRIPTION OF THE DRAWINGS

FIG. 1 is a sectional view for explaining a semiconductor device according to a first embodiment of the present invention;

FIGS. 2A and 2B are perspective views for explaining a manufacturing process of a heat conductor of the semiconductor device according to the first embodiment;

FIGS. 3A to 3F are sectional views for explaining a manufacturing process of the semiconductor device according to the first embodiment;

FIG. 4 is an enlarged sectional view for explaining a manufacturing process of a semiconductor device according to a first modification of the first embodiment;

FIG. 5 is an enlarged sectional view for explaining a manufacturing process of a semiconductor device according to a second modification of the first embodiment;

FIG. 6 is a sectional view for explaining a semiconductor device according to a second embodiment of the present invention;

FIGS. 7A and 7B are perspective views for explaining a manufacturing process of a heat conductor of the semiconductor device according to the second embodiment;

FIG. 8 is a sectional view for explaining a semiconductor device according to a first modification of the second embodiment;

FIGS. 9A and 9B are perspective views for explaining a manufacturing process of a heat conductor of the semiconductor device according to the first modification of the second embodiment;

FIG. 10 is a sectional view for explaining a semiconductor device according to a second modification of the second embodiment;

FIG. 11 is a sectional view for explaining a semiconductor device according to a third embodiment of the present invention;

FIGS. 12A and 12B are perspective views for explaining a manufacturing process of a heat conductor of the semiconductor device according to the third embodiment;

FIG. 13 is a sectional view for explaining a semiconductor device according to a first modification of the third embodiment;

FIGS. 14A and 14B are perspective views for explaining a manufacturing process of a heat conductor of the semiconductor device according to the first modification of the third embodiment;

FIG. 15 is a sectional view for explaining a semiconductor device according to a second modification of the third embodiment;

FIGS. 16A and 16B are perspective views for explaining a manufacturing process of a heat conductor of the semiconductor device according to the second modification of the third embodiment;

FIGS. 17A and 17B are a sectional view and a bottom plan view showing a semiconductor device according to a fourth embodiment of the present invention;

FIGS. 18A and 18B are a sectional view and a bottom plan view showing a semiconductor device according to a fifth embodiment of the present invention;

FIG. 19 is a sectional view showing a conventional semiconductor device;

FIG. 20 is a perspective view for explaining a heat conductor of the conventional semiconductor device;

FIGS. 21A to 21F are sectional views for explaining a manufacturing process of the conventional semiconductor device;

FIG. 22A is a front sectional view and FIGS. 22B and 22C are plan views for explaining a mechanism of deformed thin metal wires according to the side gate system; and

FIG. 23A is a front sectional view and FIGS. 23B and 23C are plan views for explaining a mechanism of deformed thin metal wires according to the top gate system.

### DESCRIPTION OF THE EMBODIMENTS

The following will describe a semiconductor device 101 according to an embodiment of the present invention with reference to the accompanying drawings. For the sake of clarity, the side of the semiconductor element mounting surface of the substrate will be described as “above” in the following explanation. Further, constituent elements having almost the same functions as those of the conventional semiconductor device 100 are indicated by the same reference numerals.

### First Embodiment

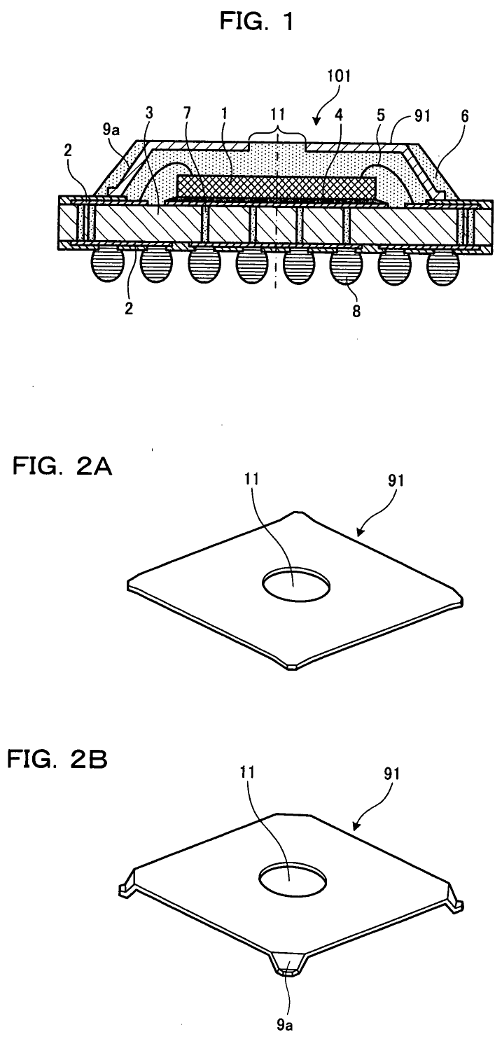

FIG. 1 is a sectional view showing a semiconductor device 101 according to a first embodiment of the present invention.

As shown in FIG. 1, the semiconductor device 101 of the present embodiment is made up of a substrate 3 made of an insulating resin and having wiring patterns 2 formed on both sides of the substrate 3, the wiring patterns 2 being electrically connected to each other through via holes 7, a semiconductor element 1 having a plurality of electrode terminals (not shown) on the underside and mounted on a top surface serving as the main surface of the substrate 3 (hereinafter, will be also referred to as a semiconductor element mounting surface) via an adhesive 4, thin metal wires 5 for electrically connecting the semiconductor element 1 and the wiring pattern 2 of the substrate 3, ball electrodes 8 arranged in a matrix form on the opposite side from the semiconductor element mounting surface of the substrate 3 and electrically connected to the wiring pattern 2 of the substrate 3, a heat conductor 91 covering the semiconductor element mounting surface of the substrate 3 and opposed to the main surface (the circuit surface of the semiconductor element 1 and the top surface of the semiconductor element 1 in FIG. 1) of the semiconductor element 1, the heat conductor 91 being trapezoidal in cross section when viewed from a side, and sealing resin 6 for sealing the semiconductor element mounting surface of the substrate 3, the semiconductor element 1, and a part of the heat conductor 91.

Particularly, in the semiconductor device 101 of the present embodiment, the opposite surface of the heat conductor 91 from the surface facing the main surface of the semiconductor element 1, that is, the top surface of the heat conductor 91 is exposed to the outside as shown in FIG. 1. Further, as shown in FIG. 2B, an opening 11 penetrating in the thickness direction is provided on a part of the top surface of the heat conductor 91 exposed to the outside.

As shown in FIGS. 1 and 2B, the opening 11 on the heat conductor 91 is disposed in the vertical direction at the center of the main surface of the semiconductor element 1 substantially parallel to the top surface of the heat conductor 91 (in other words, the opening 11 of the heat conductor 91 is superimposed on the center of the main surface of the semiconductor element 1 in plan view). Moreover, as shown in FIGS. 2A and 2B, the corners of the heat conductor 91 are bent to form supporting portions 9a protruding to the undersurface of the heat conductor 91. The undersides of the supporting portions 9a come into contact with the substrate 3.

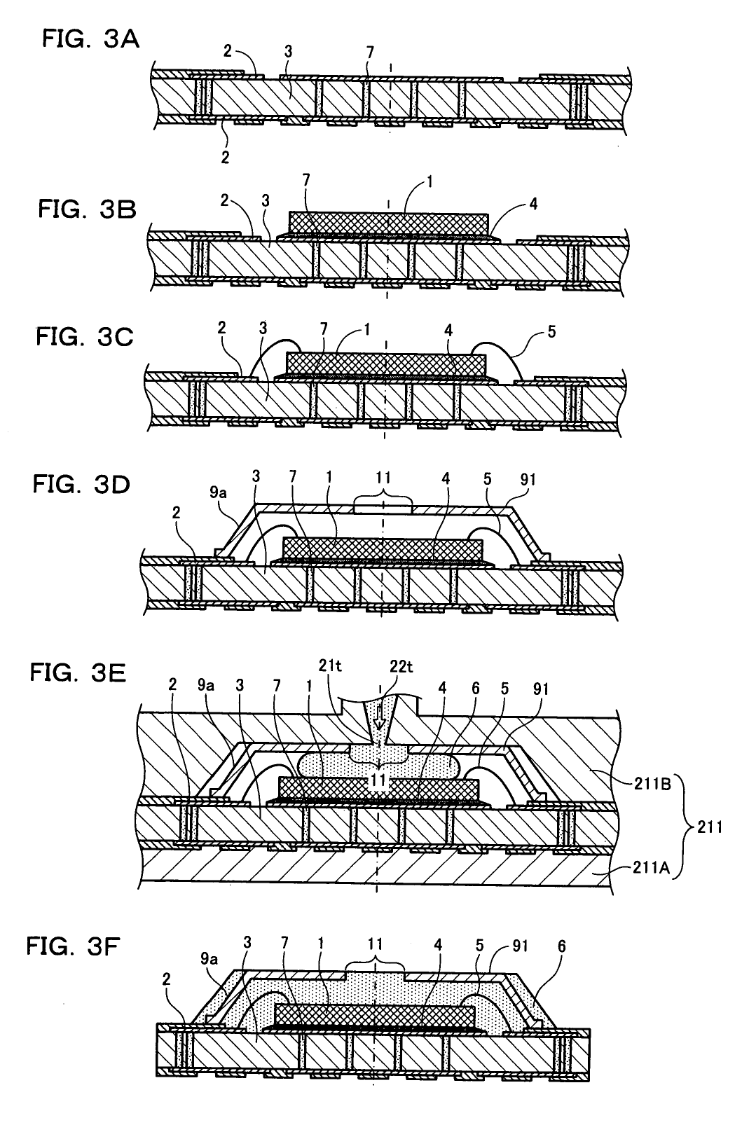

Referring to FIG. 3, a method of manufacturing the semiconductor device 101 will be described below. In FIG. 3E, reference numeral 211 denotes sealing dies, reference numeral 21t denotes an injection gate acting as an inlet, and reference numeral 22t denotes the injection direction of sealing resin.

First, in the method of manufacturing the semiconductor device 101 of the present embodiment, the substrate 3 having the wiring patterns 2 formed on both sides is prepared as shown in FIG. 3A. As shown in FIG. 3B, the semiconductor element 1 is bonded and fixed on the bonding position of the top surface of the substrate 3 via the adhesive 4, so that the semiconductor element 1 is mounted on the substrate 3.

Next, as shown in FIG. 3C, the electrode pads (not shown) of the semiconductor element 1 mounted on the substrate 3 and the wiring pattern 2 provided on the top surface of the substrate 3 are electrically connected to each other via the thin metal wires 5.

The above process is the same as that of the method of manufacturing the conventional semiconductor device 100. Next, as shown in FIG. 3D, the heat conductor 91 facing the semiconductor element 1 is brought into contact with the substrate 3. The contact portion of the heat conductor 91 may be fixed to the substrate 3 via an adhesive (not shown) and so on or may be just brought into contact with the substrate 3 without being fixed.

Referring to FIGS. 2A and 2B, a method of manufacturing the heat conductor 91 will be described below.

As shown in FIG. 2A, the heat conductor 91 is produced by etching or stamping a metallic plate into a desired shape, the metallic plate being made of a material selected from the group consisting of Cu, a Cu alloy, Al, an Al alloy, and an Fe—Ni alloy which have excellent heat conduction. As described above, the opening 11 penetrating in the thickness direction is formed on the heat conductor 91.

In this configuration, in order to prevent the thin metal wires 5 from being deformed by a flow of resin in a sealing process to be performed later, the injection gate 21t is disposed in the vertical direction at the center of the surface of the semiconductor element 1 to inject resin according to the top gate system. Moreover, in order to prevent the occurrence of thin burrs around the opening 11 in the sealing process, it is desirable that the internal diameter of the opening 11 be larger than the outside shape of the injection gate 21t. Further, the surface of an embedded part of the heat conductor 91 into the sealing resin 6 is roughed by treatment such as dimpling to have unevenness on the surface, thereby increasing adhesion with the sealing resin 6.

Next, as shown in FIG. 2B, the corners of the heat conductor 91 are bent to form supporting portions 9a protruding to the undersurface of the heat conductor 91. The undersides of the supporting portions 9a are bent in contact with the substrate 3.

In this configuration, the supporting portions 9a of the heat conductor 91 are provided only on the corners of the heat conductor 91 in order to have excellent flowability of resin in the sealing process to be performed later. In other words, in the conventional semiconductor device 100, the inclined portion is provided near the outer periphery of the heat conductor 9, whereas in the semiconductor device 101 of the present embodiment, an inclined portion is hardly present near the outer periphery of the heat conductor 91. Therefore, nothing interferes with the injection of resin, achieving high flowability of resin in the semiconductor device 101 of the present embodiment.

Further, in order to expose the uppermost surface of the heat conductor 91 from the sealing resin 6 to the outside to improve heat dissipation, the heights of the supporting portions 9a are adjusted such that a height from the uppermost surface of the heat conductor 91 to the lowermost surface of the substrate 3 is larger than the depth of the cavity of the sealing die 211 used in the sealing process to be performed later, and then the heat conductor 91 is disposed.

The following will return to the explanation of the method of manufacturing the semiconductor device 101 according to the present embodiment. As shown in FIG. 3E, the substrate 3 which has the semiconductor element 1 mounted thereon, is electrically connected via the thin metal wires 5, and is contacted to the heat conductor 91 is set on a lower die 211A of the sealing die 211 and is sealed with an upper die 211B of the sealing die 211. At this moment, the undersurface of the upper die 211B of the sealing die 211 and the top surface of the heat conductor 91 are in contact with each other. In this state, the sealing resin 6 is injected in an injection direction 22t from the injection gate 21t provided in the vertical direction of the upper die 211B of the sealing die 211. As a result, a gap on the top surface of the substrate 3 is covered with the sealing resin 6 and the top surface of the heat conductor 91 is exposed from the sealing resin 6 to the outside. The upper die 211B and the lower die 211A of the sealing die 211 are opened after the sealing resin 6 is cured.

Next, as shown in FIG. 3F, the substrate 3 having the top surface sealed with the sealing resin 6 is cut for each semiconductor chip by a rotary blade (not shown), so that the substrate 3 is divided into pieces.

Finally, solder balls are provided to form the ball electrodes 8 on external pad electrodes on the underside of the substrate 3 having been divided into pieces, so that external terminals are configured. Thus the semiconductor device 101 of FIG. 1 can be manufactured.

The heat conductor 91 does not always have to be quadrilateral as in the present embodiment and may be circular or polygonal. The shape of the opening 11 may be polygonal as long as the opening 11 is larger than the outside shape of the injection gate. Further, the supporting portions 9a of the heat conductor 9 do not always have to be contacted to the substrate 3 and thus may be contacted to the semiconductor element 1 as long as the top surface of the heat conductor 91 can be exposed. Moreover, the supporting portions 9a do not always have to be formed by bending the corners of the heat conductor 91. Another members may be bonded to the corners of the heat conductor 91 to form supporting portions as long as the top surface of the heat conductor 91 can be exposed.

The following is an effect obtained by the semiconductor device 101 and the method of manufacturing the same according to the present embodiment.

As described above, the semiconductor device 101 of the present embodiment includes the heat conductor 91 in addition to the substrate 3, the thin metal wires 5, the semiconductor element 1, and the sealing resin 6 which are provided also in the conventional semiconductor device. The heat conductor 91 is made of a heat conductive material, has the top surface exposed from the sealing resin 6 to the outside, and includes the opening 11 penetrating in the thickness direction in the exposed part. Thus it is possible to inject resin from the opening 11 while keeping the conventional function of dissipating heat generated by the semiconductor device 101 to the outside of the semiconductor device 101 through the exposed part of the heat conductor 91, and improve the adhesion with the sealing resin 6 by providing the opening 11 in the exposed part of the heat conductor 91.

In the manufacturing process of the semiconductor device 101, it is possible to adopt the top gate system allowing the injection gate 21t to be disposed above the opening 11 of the heat conductor 91 in the sealing process, so that a flow of resin causes just a small amount of deformation on the thin metal wires 5. In other words, it is possible to prevent a short circuit on the thin metal wires 5. Therefore, according to the method of manufacturing the semiconductor device 101 of the present invention, it is possible to manufacture the semiconductor device 101 without degrading or losing the function of electrical connection, so that the semiconductor device 101 can be manufactured with high manufacturing yields.

Further, the internal diameter of the opening 11 on the heat conductor 91 of the semiconductor device 101 is formed larger than the outside shape of the injection gate 21t, thereby preventing the occurrence of thin burrs around the opening 11 in the sealing process. In other words, when the internal diameter of the opening 11 on the heat conductor 91 of the semiconductor device 101 is formed smaller than the outside shape of the injection gate 21t, the sealing resin may come into a space between the periphery of the opening 11 of the heat conductor 91 and the top surface of the upper die 211B of the sealing die 211 and cause thin burrs. The configuration of the present embodiment does not cause such a problem.

Moreover, in the semiconductor device 101, since the supporting portions 9a are provided only on the corners of the underside of the heat conductor 91, the heat conductor 91 does not interfere with a flow of resin in the sealing process, thereby preventing failures such as insufficient filling.

Further, in the semiconductor device 101, since the supporting portions 9a of the heat conductor 91 are provided only on the corners, a contact area between the heat conductor 91 and the substrate 3 is small and does not interfere with the wiring patterns 2 of other signals. Thus when the heat conductor 91 is made of a conductive material, the heat conductor 91 may be used while being grounded. Therefore, the high frequency characteristics can be improved.

In conclusion, the semiconductor device 101 and the method of manufacturing the semiconductor device 101 of the present embodiment are superior to the conventional semiconductor device 100 in that failures caused by a short circuit between the thin metal wires 5 can be prevented because of a small amount of deformation of the thin metal wires 5 during the sealing process, high flowability of resin prevents insufficient filling, the semiconductor device 101 has excellent performance including high adhesion to the sealing resin 6, high manufacturing yields can be obtained, and the high-frequency characteristics can be improved by grounding the heat conductor 91.

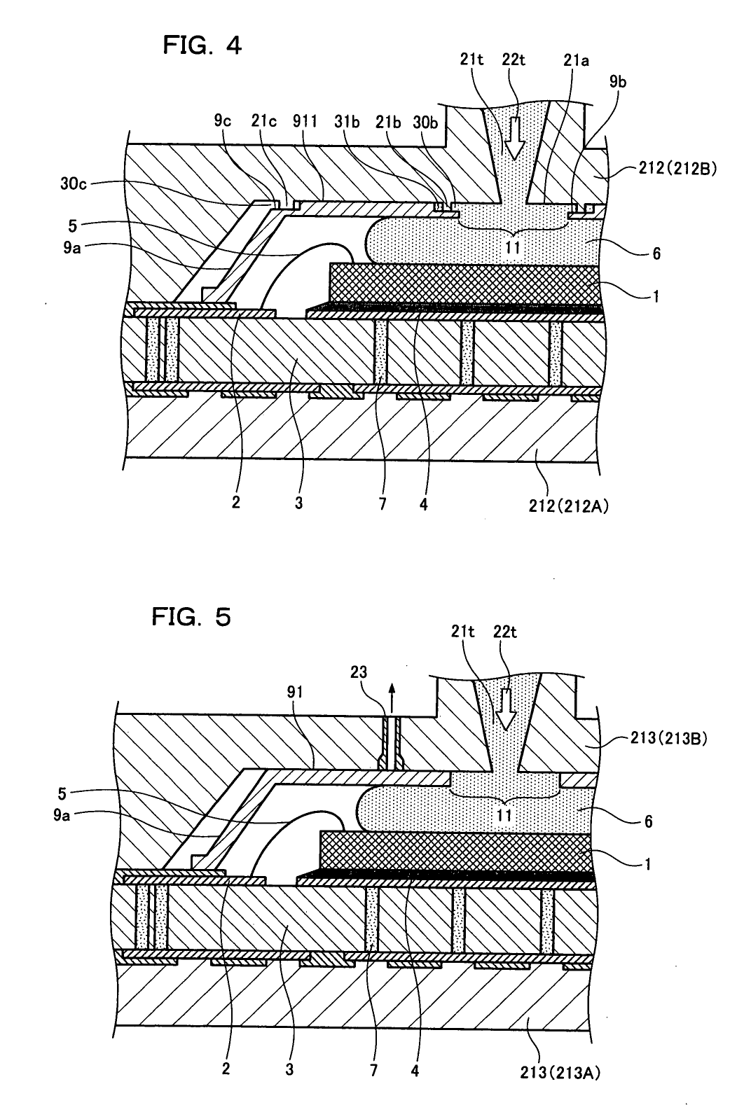

The shape of the heat conductor 91 is not limited to the shape illustrated in the present embodiment. Referring to FIG. 4, a first modification of the present embodiment will be described below. In a semiconductor device of the first modification, only the shapes of a heat conductor 911 and a sealing die 212 are different from those of the semiconductor device 101 of the present embodiment. In the following explanation, parts corresponding to those of the semiconductor device 101 of the first embodiment are indicated by the same reference numerals and the explanation thereof is omitted.

### First Modification of First Embodiment

FIG. 4 is a sectional view showing a sealing process of a semiconductor device according to a first modification.

As shown in FIG. 4, a step 9b and a step 9c are formed on the inner periphery and the outer periphery of the exposed part of a heat conductor 911 according to the first modification. The steps 9b and 9c are recessed like stairs from the exposed surface of the heat conductor 911 and are embedded in a sealing resin 6.

Further, on an upper die of a sealing die 212, a protrusion 21b and a protrusion 21c are formed substantially like rectangles in plan view on positions corresponding to the step 9b and the step 9c. The step 9b and the step 9c are larger than the protrusion 21b and the protrusion 21c in width, and the protrusion 21b and the protrusion 21c are formed substantially at the centers of the width directions of the step 9b and the step 9c, respectively. The heights of the protrusion 21b and the protrusion 21c from a reference plane 21a of an upper die 212B of the sealing die 212 are almost equal to the amounts of recesses of the step 9b and the step 9c from the top surface of the heat conductor 911. Other points are similar to those of the semiconductor device 101 of the present embodiment.

It is not always necessary to provide the protrusion 21b and the protrusion 21c on the upper die 212B of the sealing die 212. In this case, the heat conductor 911 has tapered portions instead of the steps and the area of the exposed surface is formed smaller than that of the unexposed surface of the opposite side, so that the same effect can be obtained.

An effect of the first modification is, in addition to the effect of the present embodiment, that the heat conductor 911 is prevented from falling from the sealing resin 6 because the steps 9b and 9c formed on the exposed surface of the heat conductor 911 are embedded in the sealing resin 6.

Moreover, since the step 9b and the step 9c are formed on the inner periphery and the outer periphery of the exposed part of the heat conductor 911, the sealing resin 6 is first injected into a space 30b formed by the step 9b and the upper die 212B of the sealing die 212 and then is injected into a space 30c formed by the step 9c and the upper die 212B of the sealing die 212. A part of the sealing resin 6 having been filled into the space 30b and the space 30c under a high pressure becomes stuck and starts hardening. The rest of the resin slightly displaces the heat conductor 911 downward and enters a small gap between the top surface of the step 9b and the underside of the protrusion 21b and a small gap between the top surface of the step 9c and the underside of the protrusion 21c. After that, the sealing resin 6 travels under a high sealing pressure. Thereafter, when the sealing resin 6 reaches a space 31b and a space 31c, the pressure received by the sealing resin 6 rapidly decreases. Due to the rapid decrease in the resin pressure, the heat conductor 911 is brought into intimate contact with the upper die of the sealing die 212. In this way, the deformation of the heat conductor 911 can be prevented during resin molding, thin burrs are hardly formed on the top surface of the heat conductor 911, and the top surface of the heat conductor 911 can be exposed from the sealing resin 6 to the outside.

### Second Modification of First Embodiment

FIG. 5 is a sectional view showing a sealing process of a semiconductor device according to a second modification. In the semiconductor device of the second modification, only the shape of a sealing die 213 is different from that of the semiconductor device 101 of the present embodiment. In the following explanation, parts corresponding to those of the semiconductor device 101 of the present embodiment are indicated by the same reference numerals and the explanation thereof is omitted.

As shown in FIG. 5, an upper die 213B of the sealing die 213 of the second modification has a suction hole 23 in a contact area with a heat conductor 91. The heat conductor 91 is sucked by vacuum and is fixed in contact with the upper die 213B of the sealing die 213.

An effect of the semiconductor device of the second modification is, in addition to the effect of the present embodiment, that the deformation of the heat conductor 91 can be prevented during the injection of a sealing resin 6 because the heat conductor 91 is fixed in contact with the upper die 213B of the sealing die 213. Therefore, thin burrs are hardly formed on the top surface of the heat conductor 91 and the top surface of the heat conductor 91 can be exposed from the sealing resin 6 to the outside.

### Second Embodiment

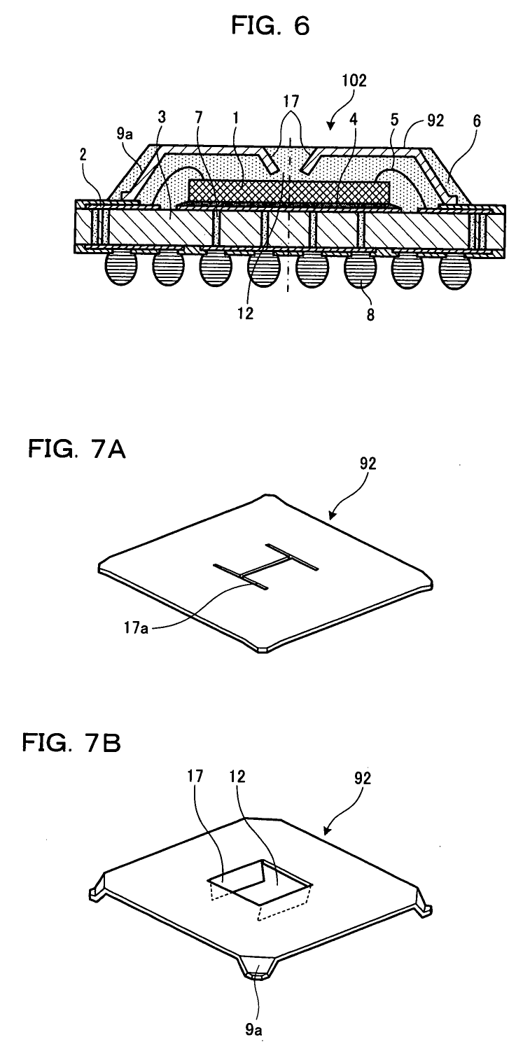

In a second embodiment, the shape of a heat conductor 92 is different from that of the semiconductor device 101 of the first embodiment. Referring to FIGS. 6, 7A and 7B, a semiconductor device 102 will be described below. The detailed explanation of parts corresponding to those of the first embodiment is omitted. FIG. 6 is a sectional view showing the semiconductor device 102 of the present embodiment. FIGS. 7A and 7B are explanatory drawings showing a manufacturing process of the heat conductor 92 of the present embodiment.

As shown in FIG. 6, in the semiconductor device 102, protrusions 17 protruding to the underside of the heat conductor 92 (in a direction that comes close to a semiconductor element 1) are provided on the sides of an opening 12 of the heat conductor 92. Further, the protrusions 17 of the heat conductor 92 are integrally formed with the heat conductor 92.

Referring to FIGS. 7A and 7B, a method of manufacturing the heat conductor 92 will be described below.

As shown in FIG. 7A, the heat conductor 92 is produced by etching or stamping a metallic plate into a desired shape, the metallic plate being made of a material selected from the group consisting of Cu, a Cu alloy, Al, an Al alloy, and an Fe—Ni alloy which have excellent heat conduction. A cut 17a penetrating in the thickness direction is formed on the heat conductor 92.

Next, as shown in FIG. 7B, supporting portions 9a identical to those of the first embodiment are formed on the corners of the heat conductor 92 and the inside of the cut 17a is bent downward, so that the protrusions 17 to be embedded in a sealing resin 6 are formed and the opening 12 is provided.

In this configuration, the protrusions 17 are formed so as not to come into contact with thin metal wires 5 and a height from the lowermost surface of the protrusion 17 to the uppermost surface of the heat conductor 92 is smaller than a height from the top surface of the semiconductor element 1 to the uppermost surface of the heat conductor 92.

Moreover, it is desirable that the opening 12 be disposed in the vertical direction at the center of the main surface of the semiconductor element 1 and the internal diameter of the opening 12 be formed larger than the outside shape of an injection gate. The opening 12 of the heat conductor 92 may be circular or polygonal as long as the shape of the opening 12 is larger than the outside shape of the injection gate. Further, it is not always necessary to form the protrusions 17 on two points. The protrusion 17 may be provided either on one point or at least three points. Other points are similar to those of the semiconductor device 101 of the first embodiment and the first modification and the second modification of the first embodiment are also applicable.

In addition to the effect of the semiconductor device 101 of the first embodiment, the semiconductor device 102 of the second embodiment has the advantage of improving adhesion between the heat conductor 92 and the sealing resin 6 because the heat conductor 92 includes the protrusions 17 embedded in the sealing resin 6. Further, the protrusions 17 are formed to come close to the semiconductor element 1, so that the heat dissipation further improves.

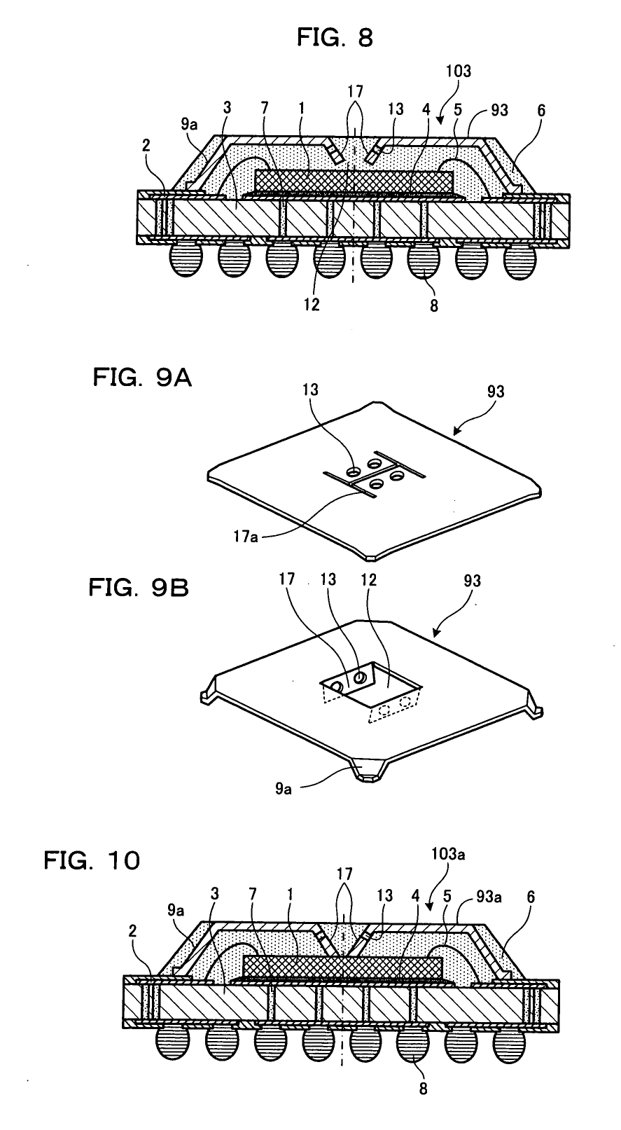

The shape of the heat conductor is not limited to the shape illustrated in the second embodiment. Referring to FIGS. 8, 9A and 9B, a first modification of the second embodiment will be described below. In a semiconductor device 103 of the first modification, only the shape of a heat conductor 92 is different from that of the semiconductor device 102 of the second embodiment. In the following explanation, parts corresponding to those of the semiconductor device 102 of the second embodiment are indicated by the same reference numerals and the explanation thereof is omitted.

### First Modification of Second Embodiment

FIG. 8 is a sectional view showing a semiconductor device 103 according to a first modification. FIGS. 9A and 9B are explanatory drawings showing a manufacturing process of a heat conductor 93 according to the first modification.

As shown in FIGS. 8 and 9B, also in the semiconductor device 103, protrusions 17 protruding to the underside of a heat conductor 93 are provided on the sides of an opening 12 of the heat conductor 93. The protrusions 17 are integrally formed with the heat conductor 92. Further, the protrusions 17 of the heat conductor 93 have holes 13 formed thereon.

Referring to FIGS. 9A and 9B, a method of manufacturing the heat conductor 93 will be described below.

As shown in FIG. 9A, the heat conductor 93 is produced by etching or stamping a metallic plate into a desired shape, the metallic plate being made of a material selected from the group consisting of Cu, a Cu alloy, Al, an Al alloy, and an Fe—Ni alloy which have excellent heat conduction. A cut 17a and the holes 13 are formed so as to penetrate in the thickness direction on the heat conductor 93. Only one hole 13 may be provided or a plurality of holes 13 may be provided. Further, the holes 13 may be shaped like polygons as well as circles. Moreover, notches may be formed instead of the holes 13.

The semiconductor device 103 is identical to the semiconductor device 102 of the second embodiment except that the holes 13 are formed on the protrusion 17 of the heat conductor 93. The cut 17a is bent to form the heat conductor 93 as shown in FIG. 9B.

An effect of the semiconductor device according to the first modification is, in addition to the effect of the present embodiment, that adhesion between the heat conductor 93 and a sealing resin 6 is further improved because the sealing resin 6 is present in the holes 13 provided on the protrusions 17 of the heat conductor 93, so that it is possible to positively prevent the heat conductor 93 from falling from the sealing resin 6.

Moreover, in a resin molding process, the holes 13 are provided on the protrusions 17 interfering with the injection of resin, so that the sealing resin 6 can pass through the holes 13. Thus the flowability of the sealing resin 6 is greatly improved.

### Second Modification of Second Embodiment

FIG. 10 is a sectional view showing a semiconductor device 103a according to a second modification of the second embodiment. In a semiconductor device 103a of the second modification, only the shape of a heat conductor 93a is different from that of the semiconductor device 103 of the first modification of the second embodiment. In the following explanation, parts corresponding to those of the semiconductor device 103 of the first modification are indicated by the same reference numerals and the explanation thereof is omitted.

As shown in FIG. 10, in the semiconductor device 103a, the lowermost surfaces of protrusions 17 of the heat conductor 93a are in contact with a main surface serving as the top surface of a semiconductor element 1. Other points are similar to those of the semiconductor device 103 of the first modification.

An effect of the semiconductor device 103a of the second modification is, in addition to the effect of the second embodiment, that heat dissipation further improves because the protrusions 17 of the heat conductor 93a are formed in contact with the semiconductor element 1.

### Third Embodiment

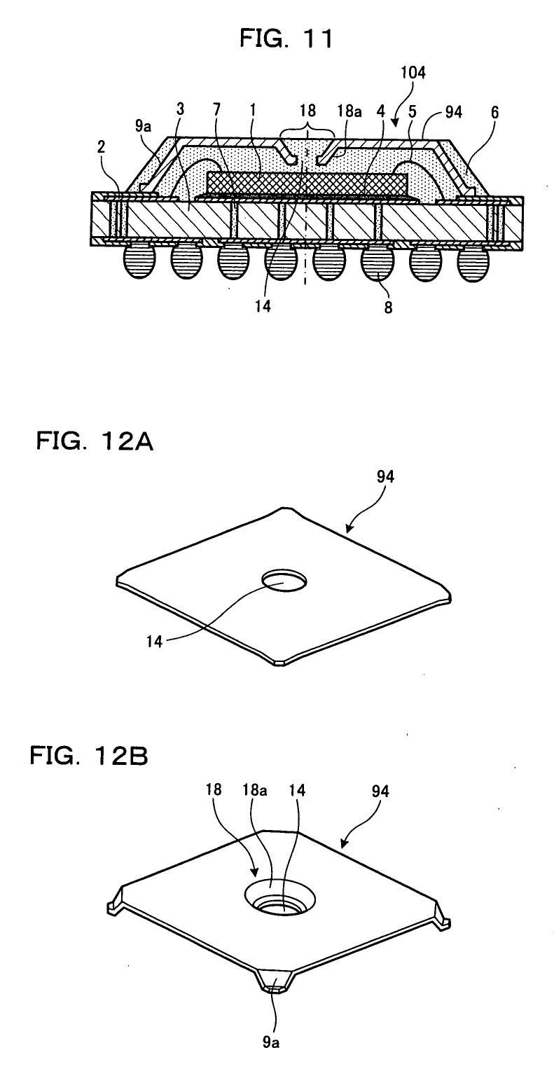

In a semiconductor device 104 of a third embodiment, the shape of a heat conductor is different from that of the semiconductor device 101 of the first embodiment. Referring to FIGS. 11, 12A and 12B, the semiconductor device 104 will be described below. The detailed explanation of parts corresponding to those of the first embodiment is omitted. FIG. 11 is a sectional view showing the semiconductor device of the third embodiment. FIGS. 12A and 12B are explanatory drawings showing a manufacturing process of the heat conductor in the semiconductor device of the third embodiment.

As shown in FIGS. 11 and 12B, in the semiconductor device 104, a recessed portion 18 is provided on a part of the exposed part of a heat conductor 94 such that the recessed portion 18 comes close to a semiconductor element 1. In the present embodiment, the recessed portion 18 is integrally formed like a cone and an opening 14 is provided on the underside of the recessed portion 18. Further, the recessed portion 18 is disposed in the vertical direction at the center of the main surface (top surface) of the semiconductor element 1 substantially parallel to the top surface of the heat conductor 94.

Referring to FIGS. 12A and 12B, a method of manufacturing the heat conductor 94 will be described below.

As shown in FIG. 12A, the heat conductor 94 is produced by etching or stamping a metallic plate into a desired shape, the metallic plate being made of a material selected from the group consisting of Cu, a Cu alloy, Al, an Al alloy, and an Fe—Ni alloy which have excellent heat conduction. As described above, the opening 14 penetrating in the thickness direction is formed on the heat conductor 94.

Next, as shown in FIG. 12B, supporting portions 9a identical to those of the first embodiment are formed on the corners of the heat conductor 94, flanging and the like are performed using the outside of the opening 14 as a flange, and the outer periphery of the opening 14 is molded downward into a cone, so that the recessed portion 18 to be embedded in a sealing resin 6 is formed.

In this configuration, the recessed portion 18 is formed so as not to come into contact with thin metal wires 5 and a height from the lowermost surface of the recessed portion 18 to the uppermost surface of the heat conductor 94 is smaller than a height from the main surface (top surface) of the semiconductor element 1 to the uppermost surface of the heat conductor 94.

Moreover, it is desirable that the opening 14 be disposed in the vertical direction at the center of the main surface of the semiconductor element 1 and the internal diameter of the recessed portion 18 be larger than the outside shape of an injection gate. The opening 14 of the heat conductor 94 may be polygonal, and the recessed portion 18 may be also polygonal as long as the shape of the recessed portion 18′ is larger than the outside shape of the injection gate. Further, a conically inclined portion 18a of the recessed portion 18 may include an opening penetrating in the thickness direction. Other points are similar to those of the semiconductor device 101 of the first embodiment, and the configurations of the first modification and the second modification of the first embodiment are also applicable.

In addition to the effect of the semiconductor device 101 according to the first embodiment, the semiconductor device 104 of the present embodiment has the advantage of improving adhesion between the heat conductor 94 and the sealing resin 6 because the heat conductor 94 includes the recessed portion 18 embedded in the sealing resin 6. Further, the recessed portion 18 is formed to come close to the main surface of the semiconductor element 1, so that the heat dissipation further improves.

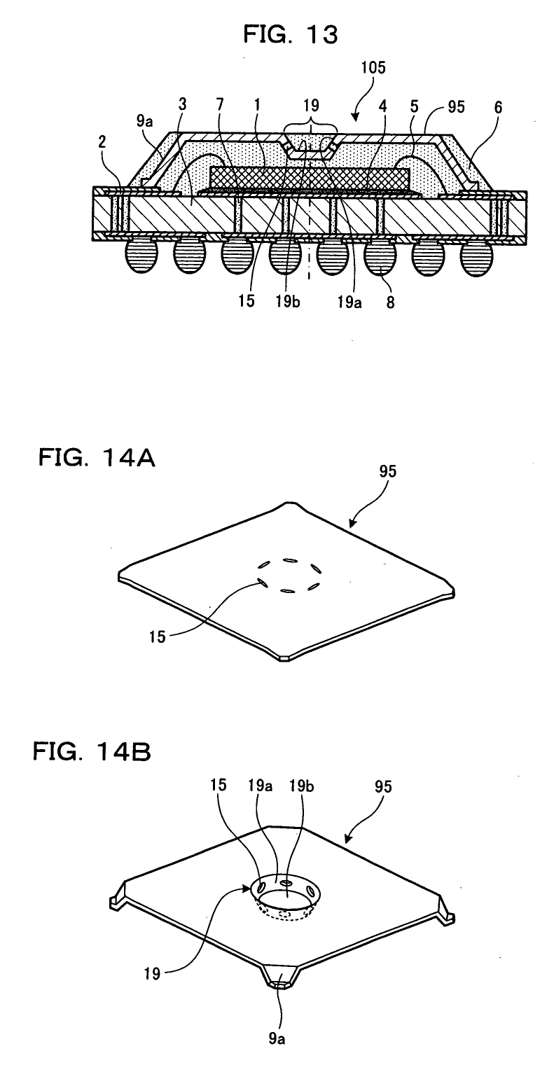

The shape of the heat conductor is not limited to the shape illustrated in the present embodiment. Referring to FIGS. 13, 14A and 14B, a first modification of the present embodiment will be described below. In a semiconductor device 105 of the first modification, only the shape of a heat conductor 95 is different from that of the semiconductor device 104 of the present embodiment. In the following explanation, parts corresponding to those of the semiconductor device 104 of the third embodiment are indicated by the same reference numerals and the explanation thereof is omitted.

### First Modification of Third Embodiment

FIG. 13 is a sectional view showing a semiconductor device of a first modification. FIGS. 14A and 14B are explanatory drawings showing a manufacturing process of a heat conductor according to the first modification.

As shown in FIG. 13, also in a semiconductor device 105, a recessed portion 19 is provided on a part of the exposed part of a heat conductor 95 such that the recessed portion 19 comes close to a semiconductor element 1. Also in the present embodiment, the recessed portion 19 is integrally formed into a cone. A plurality of openings 15 are provided only on the side of the recessed portion 19 and the underside of the recessed portion 19 has no openings (is not opened). Further, an underside 19b of the recessed portion 19 is disposed close to the main surface of the semiconductor element 1 substantially in parallel with each other.

Referring to FIGS. 14A and 14B, a method of manufacturing the heat conductor 95 will be described below.

As shown in FIG. 14A, the heat conductor 95 is produced by etching or stamping a metallic plate into a desired shape, the metallic plate being made of a material selected from the group consisting of Cu, a Cu alloy, Al, an Al alloy, and an Fe—Ni alloy which have excellent heat conduction. The plurality of openings 15 penetrating in the thickness direction are formed on the heat conductor 95. Only one opening 15 may be provided or a plurality of openings 15 may be provided. Further, the openings 15 may be shaped like polygons as well as circles.

Next, as shown in FIG. 14B, supporting portions 9a identical to those of the first embodiment are formed on the corners of the heat conductor 95, drawing and the like are performed on the heat conductor 95 to mold the outer peripheries of the openings 15 downward into a cone such that the openings 15 are disposed in an inclined portion 19a of the recessed portion 19. In this way, the recessed portion 19 to be embedded in a sealing resin 6 is formed.

In this configuration, the recessed portion 19 is formed so as not to come into contact with thin metal wires 5 and the underside 19b of the recessed portion 19 is disposed substantially in parallel with the main surface of the semiconductor element 1.

Moreover, it is desirable that the recessed portion 19 be disposed in the vertical direction at the center of the main surface of the semiconductor element 1 and the internal diameter of the recessed portion 19 be larger than the outside shape of an injection gate. The opening 15 of the heat conductor 95 may be polygonal, and the recessed portion 19 may be also polygonal as long as the shape of the recessed portion 19 is larger than the outside shape of the injection gate. Other points are similar to those of the semiconductor device 104 of the third embodiment.

The effect of the semiconductor device 105 of the first modification is, in addition to the effect of the third embodiment, that the underside 19b can be brought close to or contacted to the main surface of the semiconductor element 1 because no openings are provided on the underside 19b of the recessed portion 19 of the heat conductor 95. As shown in FIG. 13, the underside 19b of the recessed portion 19 of the heat conductor 95 is brought close to the main surface of the semiconductor element 1, improving the heat dissipation effect. The heat dissipation effect can be further improved by contacting the underside 19b to the main surface of the semiconductor element 1 (in FIG. 13, the underside 19b is not contacted).

### Second Modification of Third Embodiment

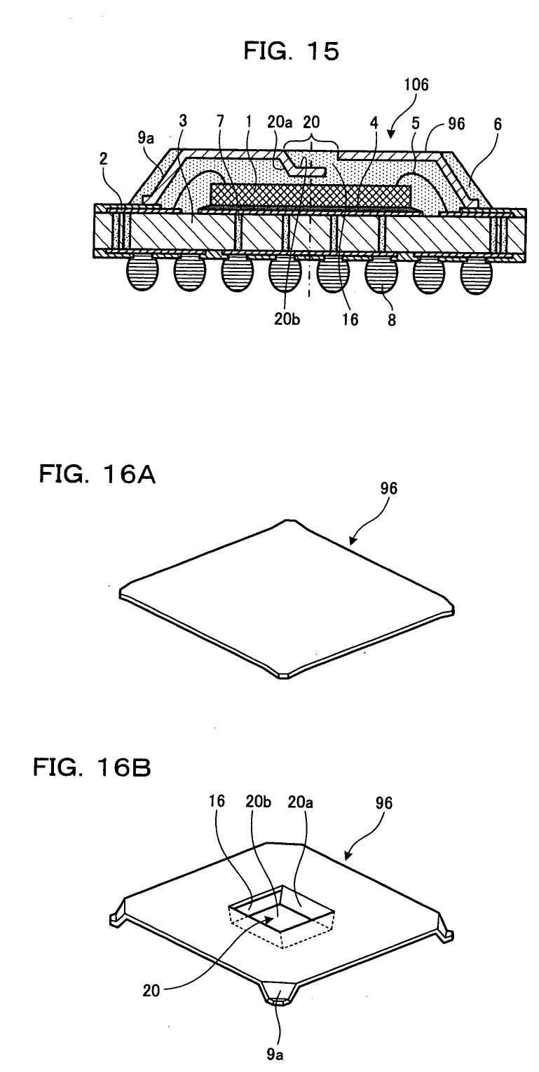

FIG. 15 is a sectional view showing a semiconductor device of a second modification. FIGS. 16A and 16B are explanatory drawings showing a manufacturing process of a heat conductor according to the second modification. In a semiconductor device 106 of the second modification, only the shape of a heat conductor 96 is different from that of the semiconductor device 104 of the third embodiment. In the following explanation, parts corresponding to those of the semiconductor device 104 in the second modification are indicated by the same reference numerals and the explanation thereof is omitted.

As shown in FIG. 15, also in the semiconductor device 106, a recessed portion 20 is provided on a part of the exposed part of a heat conductor 96 such that the recessed portion 20 comes close to a semiconductor element 1. In the second modification, the bottom of the recessed portion 20 is integrally formed by shearing or bulging as will be described later. A side of the recessed portion 20 is partially opened to form an opening 16. The underside of the recessed portion 20 remains without being opened.

Referring to FIGS. 16A and 16B, a method of manufacturing the heat conductor 96 will be described below.

As shown in FIG. 16A, the heat conductor 96 is produced by etching or stamping a metallic plate into a desired shape, the metallic plate being made of a material selected from the group consisting of Cu, a Cu alloy, Al, an Al alloy, and an Fe—Ni alloy which have excellent heat conduction.

Next, as shown in FIG. 16B, supporting portions 96a identical to those of the first embodiment are formed on the corners of the heat conductor 96, and bulging and the like are performed on the heat conductor 96 to have a sheared portion, so that the recessed portion 20 to be embedded in a sealing resin 6 is formed. Further, the opening 16 is formed on the sheared side.

In this configuration, the recessed portion 20 is formed so as not to come into contact with thin metal wires 5, and an underside 20b of the recessed portion 20 is disposed substantially in parallel with the main surface of the semiconductor element 1 and is brought close to or contacted to the main surface of the semiconductor element 1 (in FIG. 15, the underside 20b is brought close to the main surface). Moreover, it is desirable that the recessed portion 20 be disposed in the vertical direction at the center of the surface of the semiconductor element 1 and the internal diameter of the recessed portion 20 be larger than the outside shape of an injection gate. The opening 16 of the heat conductor 96 may be polygonal, and the recessed portion 20 may be also polygonal as long as the shape of the recessed portion 20 is larger than the outside shape of the injection gate. Further, a plurality of openings 16 may be provided or another opening can be formed by etching or stamping an inclined portion 20a of the recessed portion 20. Other points are similar to those of the semiconductor device 104 of the third embodiment.

An effect of the semiconductor device 106 of the second modification is, in addition to the effect of the third embodiment, that the heat dissipation effect can be improved by bringing the underside 20b of the recessed portion 20 of the heat conductor 96 to the main surface of the semiconductor element 1 as shown in FIG. 15 because no openings are provided on the underside 20b of the recessed portion 20 of the heat conductor 96. The heat dissipation effect can be further improved by contacting the underside 20b to the main surface of the semiconductor element 1.

### Fourth Embodiment

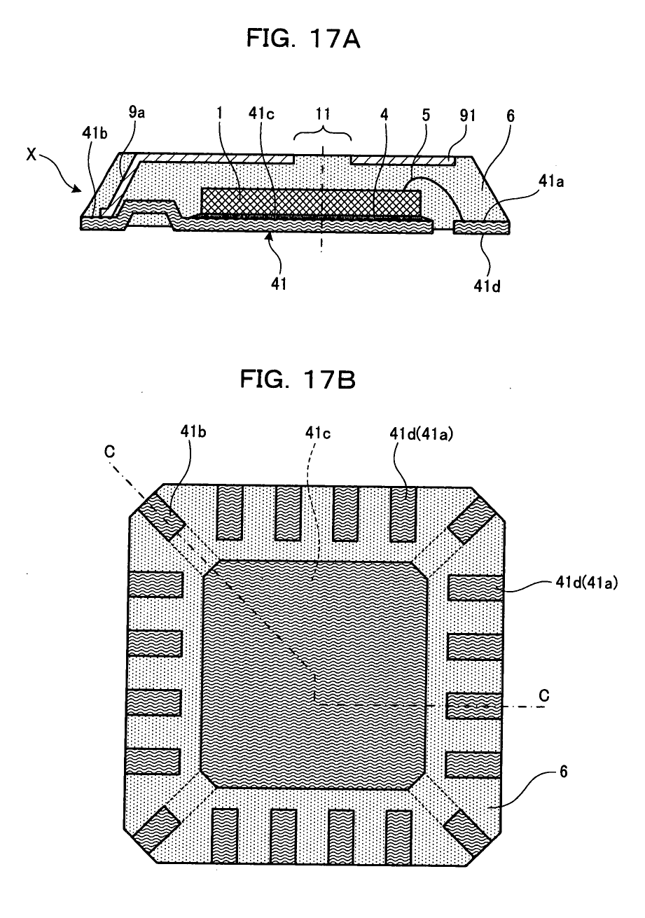

FIGS. 17A and 17B are a sectional view and a bottom plan view showing a semiconductor device according to a fourth embodiment of the present invention. FIG. 17A corresponds to a sectional view taken along line C-C indicated as a chain line in FIG. 17B. In the following explanation, parts corresponding to those of the semiconductor device 101 of the first embodiment are indicated by the same reference numerals and the explanation thereof is omitted.

As shown in FIGS. 17A and 17B, the semiconductor device of the fourth embodiment includes a lead frame 41 instead of the substrate 3 of the first embodiment. The lead frame 41 has a die pad 41c serving as a semiconductor element mounting area, a plurality of terminals provided around the die pad 41c and having external terminals 41d on the undersides and internal terminals 41a on the topsides, and hanging leads 41b for supporting the die pad 41c.

A semiconductor element 1 is fixed to the die pad 41c of the lead frame 41 with an adhesive 4, and the electrodes of the semiconductor element 1 and the topside internal terminals 41a of the lead frame 41 are electrically connected to each other via thin metal wires 5. Further, supporting portions 9a of a heat conductor 91 are fixed to the hanging leads 41b provided on the four corners of the semiconductor device. A sealing resin 6 covers with resin the semiconductor element 1, the thin metal wires 5, the semiconductor element side of the heat conductor 91, the supporting portions 9a of the heat conductor 91, and the topside internal terminals 41a. In this case, the sealing resin 6 is provided such that the top surface of the heat conductor 9, the underside of the die pad 41c, and the external terminals 41d serving as the undersides of the terminals are exposed to the outside.

Further, the opposite surface of the heat conductor 91 from the surface facing the main surface of the semiconductor element 1, that is, the top surface of the heat conductor 91 is exposed to the outside and an opening 11 penetrating in the thickness direction is provided on a part of the top surface of the heat conductor 91 exposed to the outside.

This configuration can achieve the same operation and effect as the first embodiment. Moreover, by adopting configurations similar to those of the modifications of the first embodiment, the second and third embodiments, and the modifications of the second and third embodiments, the same operations and effects can be obtained.

### Fifth Embodiment

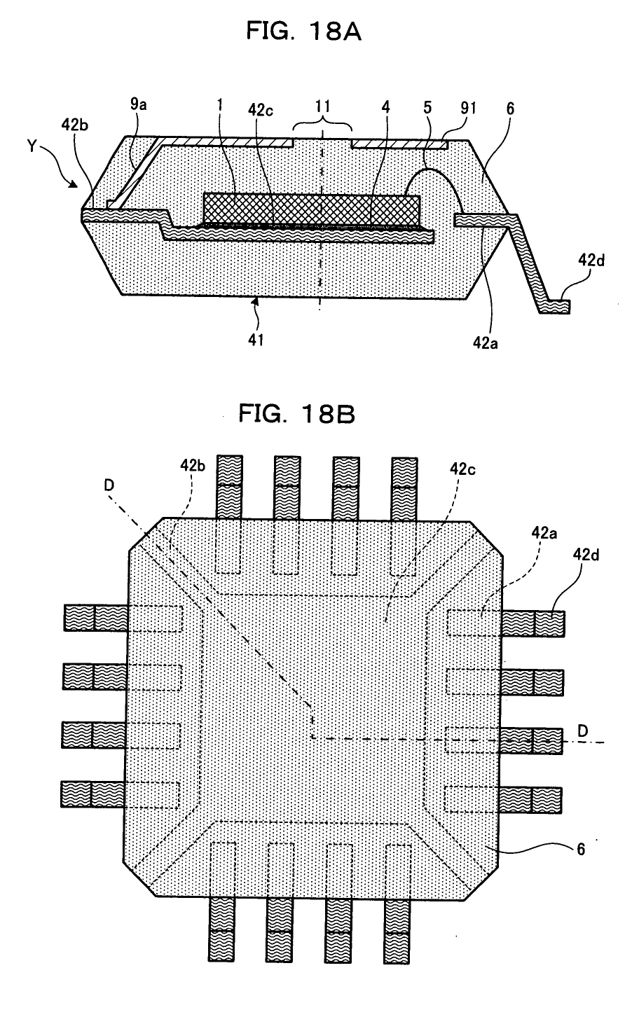

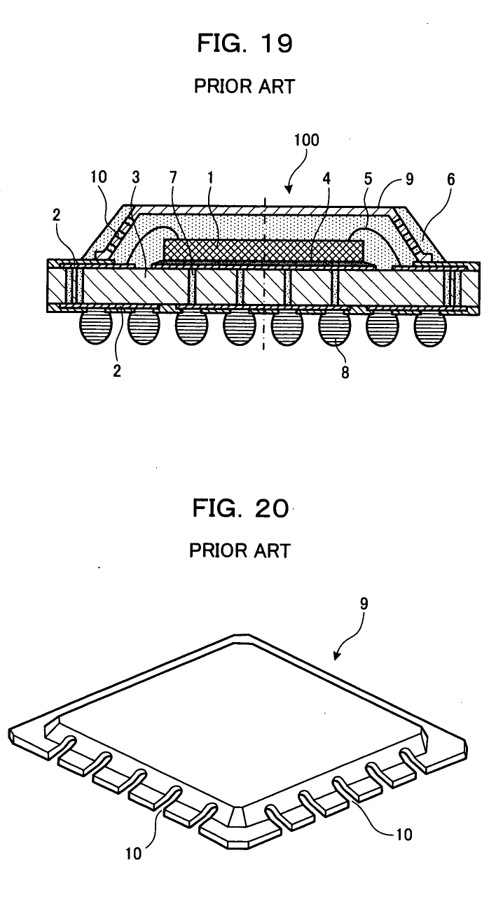

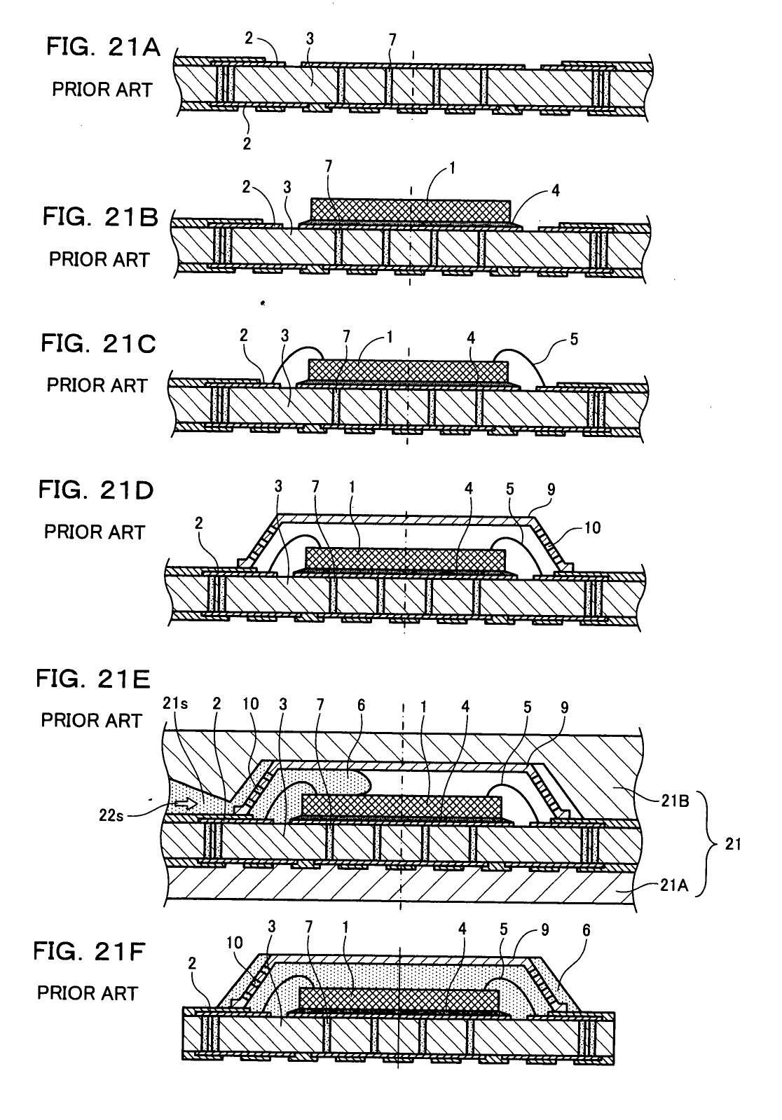

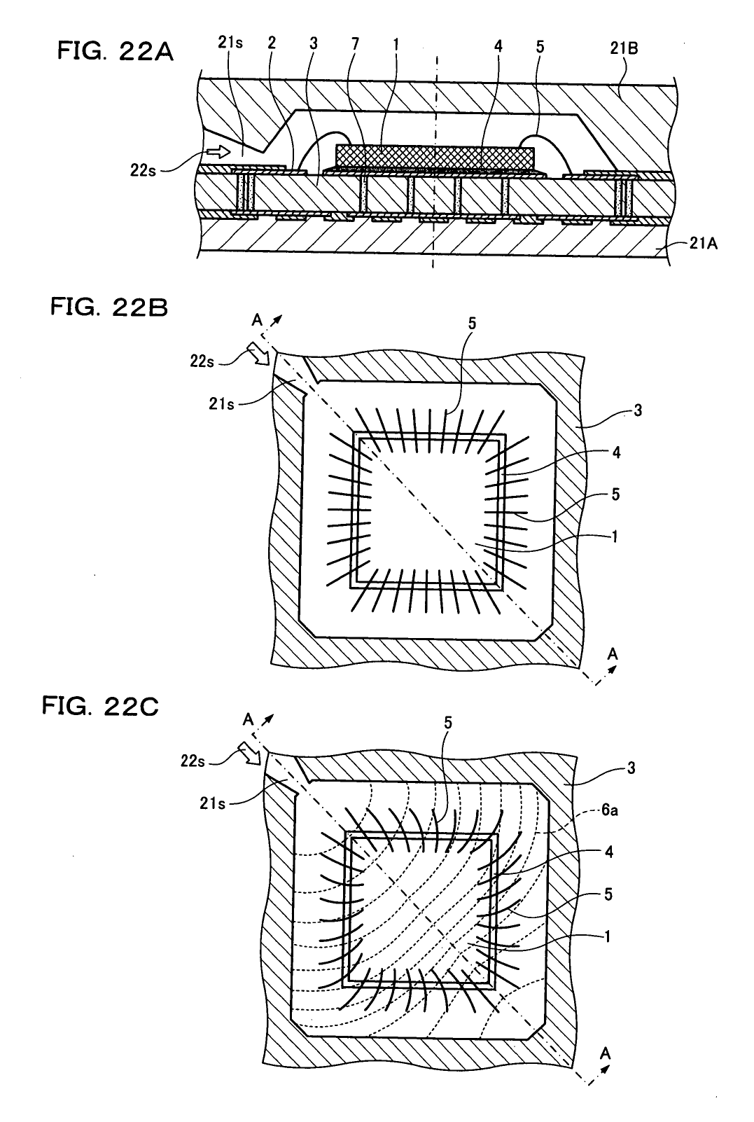

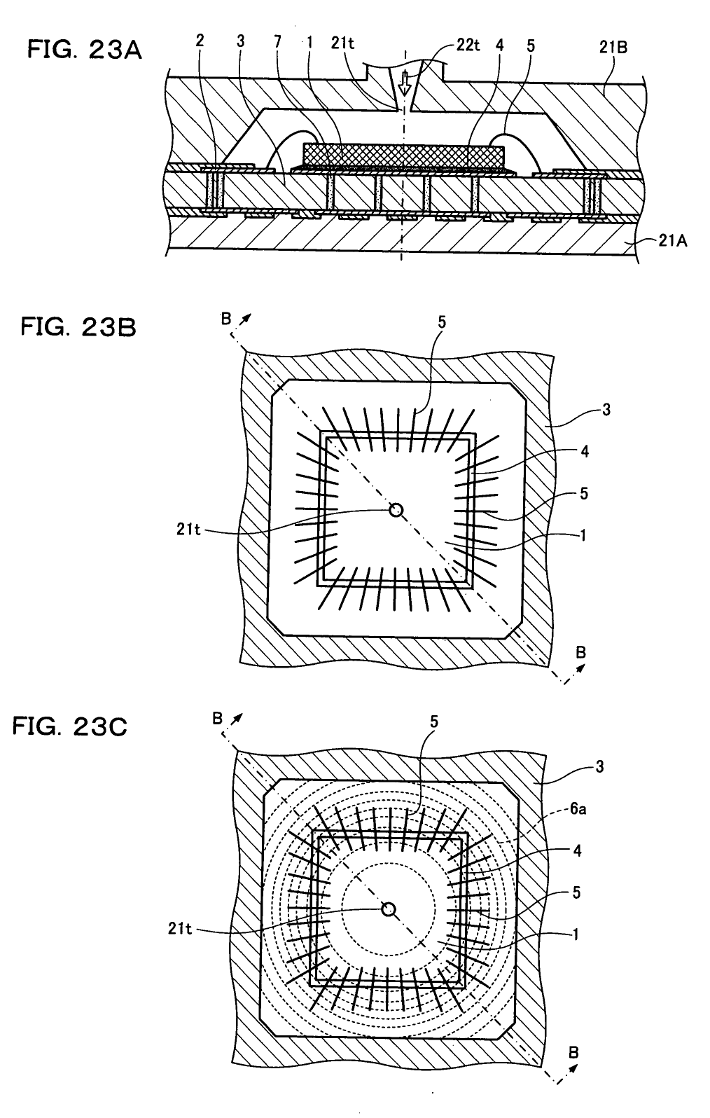

FIGS. 18A and 18B are a sectional view and a bottom plan view showing a semiconductor device according to a fifth embodiment of the present invention. FIG. 18A corresponds to a sectional view taken along line D-D indicated as a chain line in FIG. 18B. In the following explanation, parts corresponding to those of the semiconductor device 101 of the first embodiment are indicated by the same reference numerals and the explanation thereof is omitted.

As shown in FIGS. 18A and 18B, the semiconductor device of the fifth embodiment includes a lead frame 42 having a die pad 42c serving as a semiconductor element mounting area, a plurality of terminals provided around the die pad 42c and having continuously integrated internal and external terminals 42a and 42d, and hanging leads 41b for supporting the die pad 41c.

A semiconductor element 1 is fixed to the die pad 42c of the lead frame 42 with an adhesive 4, and the electrodes of the semiconductor element 1 and the internal terminals 42a of the lead frame 42 are electrically connected to each other via thin metal wires 5. Further, supporting portions 9a of a heat conductor 91 are fixed to the hanging leads 42b provided on the four corners of the semiconductor device. A sealing resin 6 covers with resin the semiconductor element 1, the thin metal wires 5, the semiconductor element side of the heat conductor 91, the supporting portions 9a of the heat conductor 91, and the internal terminals 42a. In this case, the sealing resin 6 is provided such that the top surface of the heat conductor 9 and the external terminals 42d on the sides of the terminals are exposed to the outside.

Further, the opposite surface of the heat conductor 91 from the surface facing the main surface of the semiconductor element 1, that is, the top surface of the heat conductor 91 is exposed to the outside and an opening 11 penetrating in the thickness direction is provided on a part of the top surface of the heat conductor 91 exposed to the outside.

This configuration can achieve the same operation and effect as the first embodiment. Moreover, by adopting configurations similar to those of the modifications of the first embodiment, the second and third embodiments, and the modifications of the second and third embodiments, the same operations and effects can be obtained.

In the embodiments of the present invention, there have been described a BGA package, a QFN package, and a QFP. The present invention is not limited to these packages and is also applicable to a package such as an LGA package and a COF using a film/tape and the like as a substrate, as long as resin molding is performed and a heat conductor is provided in a semiconductor device.

Although there has been described a transfer molding method as a sealing method, a potting method and so on may be used as long as resin can be injected from an opening of a heat conductor.

Particularly, the present invention is properly applied to a semiconductor device suitable for mounting a semiconductor element having a large calorific value, and a method of manufacturing the same. The present invention is particularly effective at implementing a semiconductor device having high heat dissipation and requiring stable quality.

What is claimed is:

1. A semiconductor device, comprising: a semiconductor element, a heat conductor opposed to a main surface of the semiconductor element, and a sealing resin for sealing the semiconductor element and a part of the heat conductor,
the heat conductor having a surface partially exposed from the sealing resin to an outside, the surface being opposite to the other surface facing the semiconductor element,
wherein the semiconductor device further comprises an opening penetrating in a thickness direction on a part of the surface including an exposed part of the heat conductor.

2. The semiconductor device according to claim 1, further comprising a substrate having a semiconductor element mounting area and a plurality of terminals,
wherein the heat conductor is disposed on a semiconductor element mounting surface having the semiconductor element mounting area of the substrate.

3. The semiconductor device according to claim 1, comprising: a substrate having a plurality of electrode terminals on one of surfaces of the substrate, the semiconductor element mounted on the other surface of the substrate, the heat conductor disposed on the other surface of the substrate so as to be opposed to the main surface of the semiconductor element, and the sealing resin for sealing a semiconductor element mounting surface serving as the other surface of the substrate, the semiconductor element, and the heat conductor,
the heat conductor having the surface partially exposed from the sealing resin to the outside, the surface being opposite to the other surface facing the main surface of the semiconductor element,
wherein the semiconductor device further comprises an opening penetrating in the thickness direction on the part of the surface including the exposed part of the heat conductor.

4. The semiconductor device according to claim 1, further comprising a lead frame having a semiconductor element mounting area and a plurality of terminals including internal and external terminals provided around the semiconductor element mounting area,
wherein the heat conductor is disposed on a semiconductor element mounting surface having the semiconductor element mounting area of the lead frame.

5. The semiconductor device according to claim 1, further comprising protrusions protruding to the semiconductor element, the protrusions being disposed on sides of a part having the opening of the heat conductor.

6. The semiconductor device according to claim 5, wherein the protrusions of the heat conductor are integrally formed with the heat conductor.

7. The semiconductor device according to claim 5, wherein the protrusions of the heat conductor are in contact with the semiconductor element.

8. The semiconductor device according to claim 5, wherein the protrusion of the heat conductor includes at least one of a hole and a notch.

9. The semiconductor device according to claim 1, further comprising, on a part of the surface having the exposed part of the heat conductor, a recessed portion disposed close to the semiconductor element, the recessed portion partially including an opening.

10. The semiconductor device according to claim 9, wherein the recessed portion of the heat conductor is formed into a cone.

11. The semiconductor device according to claim 9, further comprising a heat conductor having a recessed portion partially formed substantially in parallel with the main surface of the semiconductor element.

12. The semiconductor device according to claim 9, wherein the recessed portion of the heat conductor is in contact with the semiconductor element.

13. The semiconductor device according to claim 1, further comprising a step embedded in the sealing resin, the step being disposed on at least one of an outer periphery and an inner periphery of the exposed part of a heat conductor.

14. The semiconductor device according to claim 13, wherein the heat conductor has an exposed surface including the step, the exposed surface having an area smaller than that of an unexposed surface being opposite to the exposed surface.

15. The semiconductor device according to claim 1, wherein the opening of the heat conductor is disposed in a vertical direction relative to a center of the main surface of the semiconductor element.

16. The semiconductor device according to claim 1, wherein the heat conductor has protruding supporting portions on the surface opposed to the main surface of the semiconductor element.

17. The semiconductor device according to claim 2, wherein the heat conductor has supporting portions protruding to the semiconductor element mounting surface of the substrate.

18. The semiconductor device according to claim 4, wherein the heat conductor has supporting portions protruding to the semiconductor element mounting surface of the lead frame.

19. The semiconductor device according to claim 16, wherein the supporting portions of the heat conductor are formed by bending parts of the heat conductor.

20. The semiconductor device according to claim 16, wherein the heat conductor has at least three supporting portions.

21. The semiconductor device according to claim 17, wherein the supporting portions of the heat conductor are in contact with the substrate.

22. The semiconductor device according to claim 18, wherein the supporting portions of the heat conductor are in contact with the lead frame.

23. The semiconductor device according to claim 1, wherein the heat conductor has a part embedded into the sealing resin and the embedded part has a rough surface.

24. The semiconductor device according to claim 1, further comprising a plurality of thin metal wires for electrically connecting terminals and the semiconductor element.

25. The semiconductor device according to claim 2, further comprising a plurality of thin metal wires for electrically connecting the substrate and the semiconductor element.

26. The semiconductor device according to claim 4, further comprising a plurality of thin metal wires for electrically connecting the lead frame and the semiconductor element.

27. The semiconductor device according to claim 1, wherein the heat conductor is electrically connected to a ground terminal.

28. A method of manufacturing a semiconductor device, comprising the steps of:
disposing a heat conductor opposed to a main surface of a semiconductor element; and
sealing the semiconductor element and a part of the heat conductor with resin,
wherein the method further comprises the step of forming an opening penetrating in a thickness direction on a part of the heat conductor.

29. A method of manufacturing a semiconductor device, comprising the steps of:
disposing a heat conductor opposed to a main surface of a semiconductor element; and
sealing the semiconductor element and a part of the heat conductor with resin,
wherein the method further comprises the steps of:
forming, on a part of the heat conductor, a recessed portion disposed close to the semiconductor element; and
forming an opening penetrating in a thickness direction on a part of a portion corresponding to the recessed portion.

30. The method of manufacturing a semiconductor device according to claim 28, further comprising the step of mounting the semiconductor element on a substrate having a plurality of electrode terminals.

31. The method of manufacturing a semiconductor device according to claim 28, further comprising the step of mounting the semiconductor element on a semiconductor element mounting area of a lead frame having the semiconductor element mounting area and a plurality of terminals including internal and external terminals integrally provided around the semiconductor element mounting area.

32. The method of manufacturing a semiconductor device according to claim 28, comprising the steps of:
mounting a sealing die such that a part of a surface of the heat conductor is in contact with an inner wall surface of a sealing die, the surface being opposite to the other surface facing the main surface of the semiconductor element; and
performing resin molding by injecting resin into the sealing die,
wherein the method further comprises the step of forming the opening of the heat conductor such that the opening faces the inner wall surface of the sealing die.

33. The method of manufacturing a semiconductor device according to claim 29, comprising the steps of:
mounting a sealing die such that a part of a surface of the heat conductor is in contact with an inner wall surface of the sealing die, the surface being opposite to the other surface facing the main surface of the semiconductor element; and
performing resin molding by injecting resin into the sealing die,
wherein the method further comprises the step of forming the recessed portion of the heat conductor such that the recessed portion faces the inner wall surface of the sealing die.

34. A method of manufacturing a semiconductor device, comprising the steps of:
mounting a semiconductor element on a substrate, the substrate having a plurality of electrode terminals on one surface and the semiconductor element on the other surface;
disposing a heat conductor opposed to a main surface of the semiconductor element;
clamping the substrate having the semiconductor element thereon while mounting the substrate in a sealing die, and mounting the sealing die such that a part of a surface of the heat conductor is in contact with an inner wall surface of the sealing die, the surface being opposite to the other surface facing the main surface of the semiconductor element; and
injecting resin into the sealing die to seal a semiconductor element mounting surface serving as the other surface of the substrate, the semiconductor element, and the heat conductor with the resin,
wherein the method further comprises the step of forming an opening penetrating in a thickness direction on a part of a portion of the heat conductor, the portion facing the inner wall surface of the sealing die.

35. A method of manufacturing a semiconductor device, comprising the steps of:
mounting a semiconductor element on a substrate, the substrate having a plurality of electrode terminals on one surface and the semiconductor element on the other surface;
disposing a heat conductor opposed to a main surface of the semiconductor element;
clamping the substrate having the semiconductor element thereon while mounting the substrate in a sealing die, and mounting the sealing die such that a part of a surface of the heat conductor is in contact with an inner wall surface of the sealing die, the surface being opposite to the other surface facing the main surface of the semiconductor element; and
injecting resin into the sealing die to seal a semiconductor element mounting surface serving as the other surface of the substrate, the semiconductor element, and the heat conductor with the resin,
wherein the method further comprises the steps of:
forming a recessed portion on a part of a contact part between the heat conductor and the inner wall surface of the sealing die such that the recessed portion is disposed close to the semiconductor element; and
forming an opening penetrating in a thickness direction on a part of a portion corresponding to the recessed portion.

36. The method of manufacturing a semiconductor device according to claim 28, further comprising the step of performing resin molding by injecting resin from an inlet provided on the opening of the heat conductor.

37. The method of manufacturing a semiconductor device according to claim 28, further comprising: the step of performing resin molding by injecting resin from an inlet having an outside shape smaller than an inner diameter of the opening of the heat conductor.

38. The method of manufacturing a semiconductor device according to claim 30, comprising the steps of:
mounting a sealing die such that a part of a surface of the heat conductor is in contact with an inner wall surface of the sealing die, the surface being opposite to the other surface facing the main surface of the semiconductor element; and
performing resin molding by injecting resin into the sealing die,
wherein the method further comprises the step of, prior to the step of mounting the substrate in the sealing die, setting a height from a contact surface of a semiconductor element mounting surface of the substrate with the sealing die to a top of the surface opposite to the other surface facing the main surface of the semiconductor element such that the height is larger than a depth of a cavity of the sealing die on the semiconductor element mounting surface.

39. The method of manufacturing a semiconductor device according to claim 31, comprising the steps of:
mounting a sealing die such that a part of a surface of the heat conductor is in contact with the inner wall surface of the sealing die, the surface being opposite to a surface facing the main surface of the semiconductor element; and
performing resin molding by injecting resin into the sealing die,
wherein the method further comprises the step of, prior to the step of mounting the lead frame in the sealing die, setting a height from a contact surface of a semiconductor element mounting surface of the lead frame with the sealing die to a top of the surface opposite to the other surface facing the main surface of the semiconductor element such that the height is larger than a depth of a cavity of the sealing die on the semiconductor element mounting surface.

40. The method of manufacturing a semiconductor device according to claim 28, comprising the steps of:
mounting a sealing die such that a part of a surface of the heat conductor is in contact with an inner wall surface of the sealing die, the surface being opposite to the other surface facing the main surface of the semiconductor element; and
performing resin molding by injecting resin into the sealing die,
wherein the method further comprises the step of performing resin molding while sucking an exposed surface of the heat conductor to the inner wall surface of the sealing die.

41. The method of manufacturing a semiconductor device according to claim 28, comprising the steps of:
mounting a sealing die such that a part of a surface of the heat conductor is in contact with an inner wall surface of the sealing die, the surface being opposite to the other surface facing the main surface of the semiconductor element; and
performing resin molding by injecting resin into the sealing die,
wherein the method further comprises the step of forming a first protrusion opposed to a step embedded in a sealing resin formed on an inner periphery of an exposed part of the heat conductor, and sealing the step on the inner periphery of the exposed part and the first protrusion with resin while bringing the step and the first protrusion into contact with each other.

42. The method of manufacturing a semiconductor device according to claim 28, comprising the steps of:
mounting a sealing die such that a part of a surface of the heat conductor is in contact with an inner wall surface of the sealing die, the surface being opposite to the other surface facing the main surface of the semiconductor element; and
performing resin molding by injecting resin into the sealing die,
wherein the method further comprises the step of forming a second protrusion opposed to a step embedded in a sealing resin formed on an outer periphery of an exposed part of the heat conductor, and sealing the step on the outer periphery of the exposed part and the second protrusion with resin while bringing the step and the second protrusion into contact with each other.
